(19) United States
(12) Patent Application Publication
(10) Pub. No.: US 2006/0105519 A1
(43) Pub. Date: May 18, 2006

(54) DRAM on SOI

(75) Inventors: Jonathan Philip Davis, Mechanicsville, VA (US); Robert Fuller, Mechanicsville, VA (US); Michael Rennie, Mechanicsville, VA (US)

Correspondence Address: BRINKS HOFER GILSON & LIONE;INFINEON, PO BOX 10395, CHICAGO, IL, 60610, US

(73) Assignee: Infineon Technologies Richmond, L.P

(21) Appl. No.: 10/991,061

(22) Filed: Nov. 17, 2004

(51) Int. Cl. H01L 21/8244

(52) U.S. Cl. 438/238

(57) ABSTRACT

In a semiconductor manufacturing process for a dynamic random access memory, a buried insulator layer such as a buried SIMOX layer between trench capacitors isolates the capacitor from the access transistor, limiting leakage, improving device performance and simplifying manufacturing.

### BACKGROUND

The present application relates generally to semiconductor devices and manufacturing techniques. More particularly, the present application relates to forming a dynamic random access memory in a silicon-on-insulator structure.

Dynamic random access memory devices (DRAMs) are volatile data storage devices in which the presence or absence of charge stored on a capacitor represents a stored logic value. The storage capacitor is combined with an access transistor to define a memory cell. Semiconductor devices have been developed containing 256 Mbytes of such memory cells, along with associated addressing and control circuitry. Future DRAM generations will store even more data.

As the storage requirements for DRAMs have increased, the physical size of the transistors and capacitors have decreased. Sizes need to be reduced to allow the additional devices to be packed physically closer together. Also, smaller sized is needed to reduce parasitic effects such as capacitance and inductance that can reduce the performance of the DRAM circuitry. At the same time, the capacitance of the capacitor, which is a measure of its charge-storing ability, needs to be kept sufficiently large to ensure reliable reading, writing and storage of data in the memory cell. Capacitance is generally proportional to the surface area of the two adjacent regions that form the capacitor.

One method for resolving these contradictory design goals has been development of deep trench capacitors. In addition to the transistors and interconnects that are formed on the surface of a semiconductor substrate, a deep trench is etched into the surface and filled with conductive material to define one plate of the memory cell capacitor. The access transistor is defined at the surface to permit charge to be stored on the capacitor (writing the cell) or removed from the capacitor (reading the cell).

Deep trench capacitors thus allow dense packing of memory cells by forming vertical capacitors with surface area to store sufficient charge to reliably retain stored data. Additional processing steps are required to define and fill the deep trenches, but the result is a substantial increase in the amount of data stored on a single semiconductor device.

In order to reliably store charge, the capacitor must be electrically isolated from regions around the capacitor structure. This includes the lightly doped region or well in which the capacitor is formed. This also includes adjacent active devices, such as the access transistor. If the capacitor is not adequately isolated, charge leakage will occur and the memory cell will fail to retain stored data.

One technique that has been used for isolating charge storage capacitors in DRAMs is reverse-biased diode isolation. The capacitor is formed of n-type semiconductor material in a well of p-type material. The p-type material is electrically biased to a negative potential so that a reverse-biased diode is formed by the n and p material. Leakage from the capacitor is limited to the very small reverse-leakage current of the isolation diode. For some technologies, this type of isolation has been adequate. However, as geometries have shrunk and the amount of stored charge has decreased, even the small reverse-leakage current is too great for reliable data storage.

FIG. 1 is a cross section of a prior art DRAM memory cell 100 which adds oxide isolation to improve the electrical isolation of the storage capacitor of the memory cell. The memory cell 100 is formed in a semiconductor substrate 102 such as a silicon wafer. The substrate 102 has been patterned at its surface 104 to define a p-well 106 with an n-diffusion 108. Conventional ion implantation is used to dope the well 106 and the diffusion 108. A deep trench 110 has been etched in the surface 104 of the silicon. A collar oxide 112 has been formed on the inner wall 114 of the trench 110 and the trench 110 has been filled with polysilicon or poly 116 which is doped n+. The bottom edge 113 of the collar oxide 112 is approximately 1 μm below the surface 104 of the substrate 102. Finally a shallow trench oxide (STI) 118 is formed at the surface 104. The n+ poly 116 forms one plate of a storage capacitor 120; the p-well 106 forms the other plate. The n-diffusion 108 is the source of the access transistor 122. Another n-diffusion region 126 defines the drain of the access transistor. Both the source and drain are self-aligned to a gate 124 which is a part of the word line which is activated to access the row of a memory cell array including the memory cell 100.

For the conventional memory cell 100 of FIG. 1, the large physical dimensions of the plates of the capacitor 120 need to be kept well isolated from the access transistor 122. This is achieved in this conventional memory cell by the isolating collar oxide 112 within the top portion of the trench 110 along with a series of graded implants form the p-well 106. The p-well 106 is relatively deep. In one exemplary embodiment, the bottom of the collar oxide 112 is approximately 1.0 μm from the surface 104.

While the structure of FIG. 1 has been successful at providing high performance, high density memory devices, there is room for additional improvement for future product generations. For example, the diode isolation between the capacitor plate and the p-well remains a source of leakage of charge stored on the capacitor. Also, the collar oxide introduces an additional vertical leakage path which reduces reliability of the memory cell. Further, the series of graded implants used in the p-well introduce additional processing steps just for the purpose of isolating the trench capacitor.

According, there is a need for an improved DRAM memory cell structure and method for making such a memory cell.

### BRIEF SUMMARY

In a semiconductor manufacturing process for a dynamic random access memory, a buried insulator layer such as a buried SIMOX layer between trench capacitors isolates the capacitor from the access transistor. This has the benefit of limiting leakage between the capacitor and the transistor, improving device performance. This has the further benefit of simplifying manufacturing and improving manufacturing yields.

### BRIEF DESCRIPTION OF THE DRAWINGS

FIG. 1 is a cross section of a prior art DRAM memory cell;

FIG. 2 is a cross section of an improved DRAM memory cell; and

FIGS. 3-6 are a series of cross sectional views showing manufacture of the improved DRAM cell of FIG. 2.

### DETAILED DESCRIPTION OF THE PRESENTLY PREFERRED EMBODIMENTS

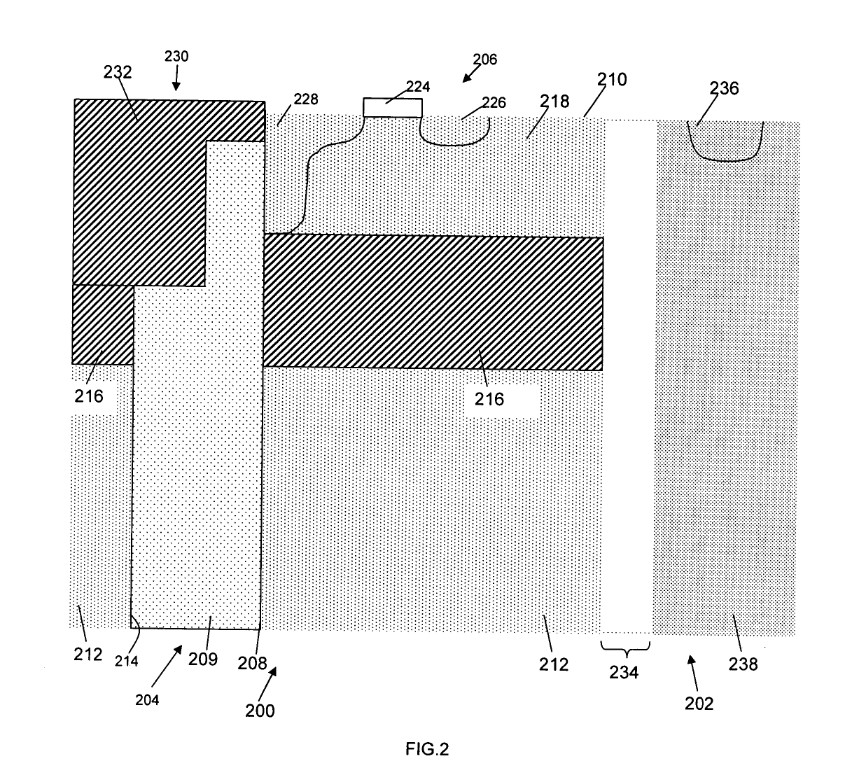

FIG. 2 is a cross section of an improved DRAM memory cell 200, along with a substrate contact 202. The DRAM memory cell 200 includes a deep trench capacitor 204 and an access transistor 206.

The deep trench capacitor 204 is formed by etching a deep trench 208 in the surface 210 of a semiconductor substrate 212. Any suitable etching technique may be used, such as plasma etching. Preferably, the walls of the trench 208 are substantially perpendicular to the surface 210 of the wafer 212. Any suitable trench profile, such as round, square or rectangular may be used. The trench 208 forms a portion of the capacitor 204, so structure of the trench is preferably optimized to maximize capacitor performance, e.g., by limiting charge leakage from the capacitor 204.

Following etching of the deep trench 208, a node dielectric 214 is deposited on the inside surface of the trench 208. The node dielectric 214 may be any suitable insulator such as silicon nitride, silicon dioxide, or a combination of materials. The “node” refers to the electrical node which is common between the capacitor 204 and the access transistor 206. Charge stored on this node represents data stored in the memory cell. For example, the presence of charge stored on the node corresponds to a stored logic 1 value and the absence of stored charge corresponds to a stored logic 0 value. This may be reversed in some applications. The node dielectric electrically isolates the node from the semiconductor substrate 212, which forms the other side of the capacitor 204. The substrate 212 is electrically tied to a bias voltage through the substrate contact 202.

Following formation of the node dielectric 214, the trench 208 is filled with a conducting material 209. In one embodiment, the trench is filled with polysilicon doped n+. Any suitable material to produce acceptable charge storage effects may be used.

Prior to filling the trench 208, a buried insulator layer 216 is formed. In the preferred embodiment the buried insulator layer 216 is formed by using a high-dose oxygen implant during trench processing. One suitable buried insulator layer is a separation-by-implanted oxygen (SIMOX) layer in which oxygen is ion implanted in the single crystal silicon substrate 212 to form a buried oxide layer. Following implanting of the oxygen, the substrate is processed to activate the oxygen and form an insulating layer of silicon dioxide. The substrate 212 below the buried insulator layer 216 remains single crystal silicon doped to n-type. The single crystal silicon above the buried insulator 216 is subsequently doped p-type to form a p-well 218 for formation of the access transistor 206.

The access transistor 206 includes a gate stack 224 and source/drain diffusions 226, 228. The gate stack 224 includes an insulator formed on the surface 210 of the semiconductor substrate 212 and a conductive gate forming the gate of the access transistor 206. Other conventional techniques for optimizing field effect transistor performance, such as inclusion of a lightly doped drain (LDD), etc. may be employed in fabrication of the access transistor.

The source/drain diffusion 226 operates as the drain of the access transistor 206. The source/drain diffusion 228 is electrically common with the storage node of the storage capacitor 204 and operates as the source of the access transistor 206. Preferably, the source/drain diffusion 228 extends through the p-well 218 to the top of the buried insulator layer to completely cut off any leakage path between the capacitor 204 and the transistor 206. When positive gate-to-source voltages is applied to the access transistor, the transistor 206 turns on and drain current flows in the source/drain diffusion 226. Preferably, the gate stack 224 is a portion of the word line which activates a row of a memory array including the memory cell 200. When the word line is driven high, a positive gate-to-source voltage is applied, turning on the access transistor 206. The source/drain diffusion 226 may be electrically coupled to a bit line of the memory cell array including the memory cell 200. When the access transistor 206 is turned on, the memory cell 206 may be written or read by applying appropriate signals to the bit line. Access and operation of a memory cell is well known in the relevant art and it is intended that the improved memory cell of FIG. 2 can accommodate these conventional techniques.

For isolating the capacitor 204 and limiting charge leakage therefrom, a shallow isolation trench 230 is etched adjacent to the capacitor 204 after the deep trench 208 has been filled. Preferably, the buried insulator layer 216 is shallow enough, and the shallow trench is deep enough so that the shallow trench 230 reaches the buried insulator layer 216. The shallow trench 230 may be formed using any suitable etching technique. After etching, the trench 230 is filled with dielectric material, such as oxide 232. Since the oxide 232 filling the trench 230 reaches the buried insulator layer 216, the access transistor 206 is electrically isolated vertically, limiting or eliminating charge leakage. The shallow trench isolation is masked from the side 234 of the capacitor 204 proximate the access transistor 206 so that the conductive material filling the deep trench 208 and forming the storage node of the capacitor 204 is electrically common with the source/drain diffusion 228 of the access transistor.

In one embodiment, a row of the memory array including the memory cell 200 includes a plurality of capacitors including capacitor 204 and a plurality of access transistors including the access transistor 206 aligned in a row along the word line forming the gate stack 224. Such a row extends out of the plane of the page of FIG. 2. In FIG. 2, the substrate contact 202 may actually be spaced a distance away from the memory cell 200, as indicated by the space 234 in the drawing. The spacing between the substrate contact 202 and the memory cell 204 will typically be defined by rules of photolithography and semiconductor processing. Accordingly, one or more additional rows of memory cells may be aligned with the row including the memory cell 200 to form a portion of a memory array.

The substrate contact 202 includes a heavily doped n+ region 236 to a portion of n-well 238. The n-well 238 is electrically common with the semiconductor substrate 212. The substrate contact 202 permits the electrical biasing of the n-well 238 and the semiconductor substrate 212. The n+ region 236 is doped to permit formation of an ohmic contact to the single crystal silicon of the n-well 238.

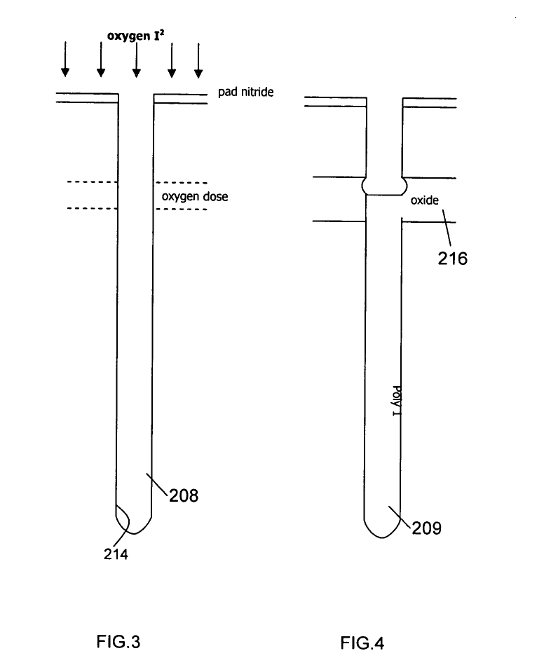

FIGS. 3-6 are a series of cross sectional views showing manufacture of the improved DRAM cell of FIG. 2. FIG. 3 is a cross section of the memory cell of FIG. 2 shown after the deep trench 208 has been etched and after the node dielectric 214 is deposited in the deep trench 208. In the step illustrated in FIG. 3, oxygen species is implanted in the regions of the semiconductor substrate away from the substrate contact. During this implant step, the substrate contact is protected by photoresist or other material. The photoresist prevents the oxygen species from entering the semiconductor material so that subsequently, no buried insulator layer is formed in the region of the substrate contact. Exemplary implant values for the oxygen implant are a dose of 5×10¹⁷ to 5×10¹⁸ cm⁻³ at an energy of 100-500 keV. Other values may be substituted.

FIG. 4 is a cross section showing the memory cell of FIG. 2 after a node reoxidation step. This step activates the oxygen implanted in the previous step to form the buried insulating layer. Subsequently, the deep trench 208 is filled with a first polysilicon material 209. Subsequently, a recess etch is performed along with a node nitride strip. The recess etch is require so that the dielectric can be removed from the buried strap region. The node dielectric would prevent ohmic contact between the trench capacitor and the cell transistor.

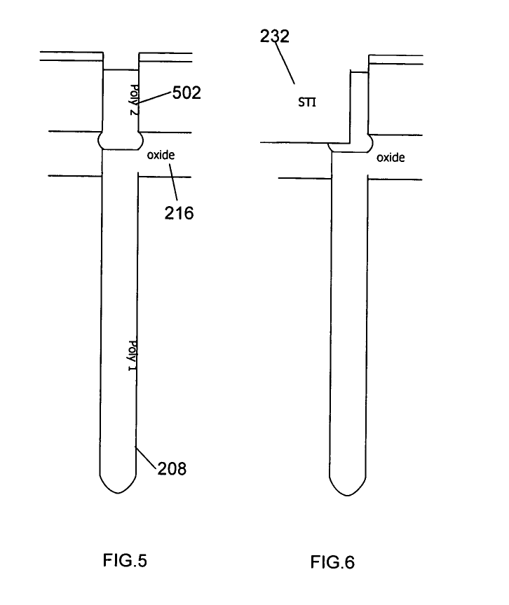

FIG. 5 is a cross section showing the memory cell of FIG. 2. At the illustrated step, a buried strap nitride layer is deposited and patterned. The buried strap nitride prevents re-crystallization of the polysilicon. Such re-crystallization would cause defects and leakage. The deep trench 208, partially filled with polysilicon 209 (referred to as poly 1 in FIG. 5), is further filled with polysilicon 502 (referred to as poly 2 in FIG. 5). This step is followed by a recess etch.

FIG. 6 is a cross section showing the memory cell of FIG. 2 after etching to define a shallow trench and filling the shallow trench with oxide 232 or other insulator (referred to in FIG. 6 as STI or shallow trench isolation).

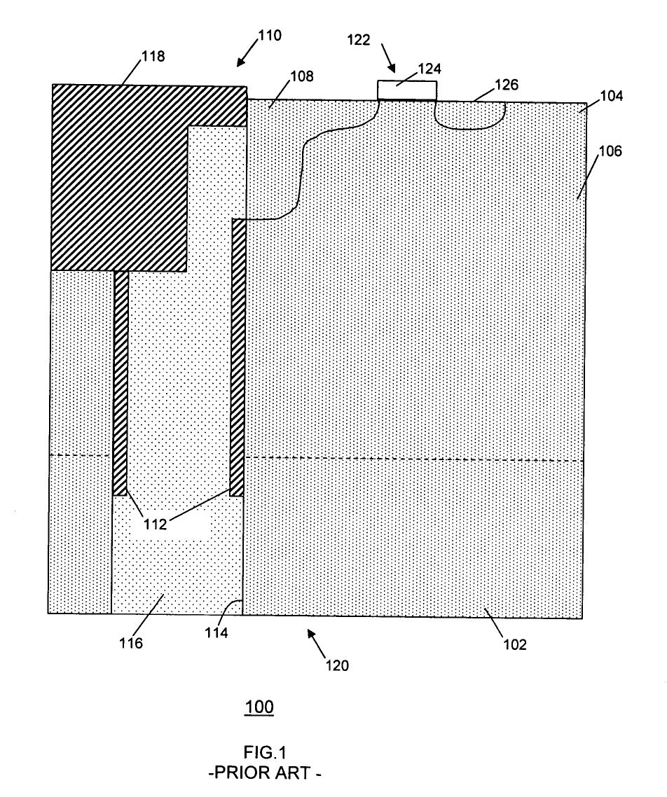

From the foregoing, it can be seen that the present embodiments provide an improved dynamic random access memory cell with improved isolation characteristics. Prior to filling the deep trench which forms the capacitor, oxygen is implanted and activated to form a SIMOX buried insulator layer. This technique provides performance advantages relative to prior designs. For example, the disclosed embodiment substantially eliminates the vertical leakage path between the transistor and capacitor. Since the collar oxide (shown in FIG. 1) is eliminated, the new embodiment affords a potentially larger capacitor area because the buried oxide takes up less vertical space than the collar oxide. Alternatively, the trench capacitor can be made shallower and still yield the same capacitance value. This technique provides more efficient manufacturing processes, as well. For example, a poly 3 deposition and poly 3 recess etch may be omitted from the conventional process flow. Poly 3 is in the buried strap region. The new technique simplifies the p-well implant scheme relative to the conventional technique, since no deep implant is required. In the new technique, the bottom of the buried strap is defined by the oxygen implant rather than a poorly controlled recess etch, improving overall process yield.

It is therefore intended that the foregoing detailed description be regarded as illustrative rather than limiting, and that it be understood that it is the following claims, including all equivalents, that are intended to define the spirit and scope of this invention.

1. A method for forming a data storage element on a semiconductor substrate, the method comprising:
forming deep trenches in a surface of the semiconductor substrate;
forming a buried insulator layer in the semiconductor substrate between the deep trenches to define an active well portion above the buried insulator layer and a substrate portion below the buried insulator layer;
filling the plurality of deep trenches with polysilicon to define a storage node of a capacitor for storing data in the storage element; and
defining an access transistor electrically common with the storage node in the active well portion of the semiconductor substrate.

2. The method of claim 1 wherein forming the buried insulator comprises:
implanting oxygen in the semiconductor substrate between the deep trenches at a predetermined depth; and
activating the oxygen to form the buried insulator layer.

3. The method of claim 1 further comprising:
etching the active well portion adjacent to the filled deep trenches and away from the access transistor; and
filling the etched active well portion with an insulator to electrically isolate the storage node of the capacitor.

4. A method for forming a semiconductor device on a semiconductor substrate, the method comprising:
forming a plurality of deep trenches in a surface of the semiconductor substrate;
implanting oxygen in the semiconductor substrate between the plurality of deep trenches at a depth sufficient to define an electrical isolation region adjacent to the deep trenches;
activating the oxygen to form an electrically insulating layer between a substrate portion of the semiconductor substrate and a well portion of the semiconductor substrate;
filling the plurality of deep trenches with polysilicon to define a storage node of a capacitor; and
defining an access transistor electrically common with the storage node in the well portion of the semiconductor substrate.

5. The method of claim 4 further comprising;
etching shallow trenches in the well portion and in a portion of the polysilicon filling the deep trenches on a side of the deep trenches away from the access transistors; and
filling the shallow trenches with insulating material to electrically isolate the storage node of the capacitor.

6. The method of claim 5 further comprising:
etching into the electrically insulating layer before filling the shallow trenches.

7. The method of claim 4 further comprising:
protecting a portion of the surface of the semiconductor substrate from implantation of the oxygen to define a substrate contact to the substrate portion; and
forming an electrical contact to the substrate contact.

8. A memory device comprising:
a plurality of memory cells, each memeory cell including
an access transistor formed in an active well disposed on a semiconductor subtarate, and
a capacitor adjacent to the access transistor and including as a storage node a deep trench filled with doped polysilicon isolated by a node dielectric in the deep trench from a plate node formed by a biased well of the semiconductor substrate, the storage node electrically common with the access transistor for reading and writing the memory cell; and
a buried insulator layer formed in the semicondutor substrate and isolating the active well from the biased well to limit leakage from the capacitor.

9. The memory device of claim 8 further comprising a shallow trench oxide on a a side of the capacitor away from the access transistor, the shallow trench oxide extending to the buried insulator layer to electrically isolate the storage node.

10. The memory device of claim 8 further comprising a substrate contact electrically contacting the biased well of the semiconductor substrate, the substrate contact formed in a region in which the formation of the buried insulator is blocked.

11. The memory device of claim 8 wherein the buried insulator comprises an oxide layer formed by implanting oxygen at a predetermined depth in the semiconductor substrate and by activating the oxygen to form the buried insulator.

12. The memory device of claim 11 wherin the buried insulator layer is patterned to define subtrate contacts for electrically contacting the biased well of the semiconductor substrate, the buried insulator layer being absent from the substare contacts.

13. The memory device of claim 8 wherein the active well comprises p-type silicon, the biased well comprises n-type silicon and the buried insulator layer comprises silicon dioxide.

14. The memory device of claim 13 further comprising an n-well in portions of the semiconducotr substrate where the buried insulator layer is absent, the n-well forming an electrical contact to the biased well to bias the plate node of the capacitor.
